(19) United States
(12) Patent Application Publication
(10) Pub. No.: US 2014/0095094 A1
(43) Pub. Date: Apr. 3, 2014

(54) Imaging Systems and Methods

(71) Applicants: Frank Hermann Sotzik, East Victoria Park (AU); Javier Andre Leicester, Woodvale (AU); Venkateswara S. Venkatesan, Thornlie (AU)

(72) Inventors: Frank Hermann Sotzik, East Victoria Park (AU); Javier Andre Leicester, Woodvale (AU); Venkateswara S. Venkatesan, Thornlie (AU)

(21) Appl. No.: 13/927,444

(22) Filed: Jun. 26, 2013

(30) Foreign Application Priority Data
Jun. 26, 2012 (AU) 2012203719

(51) Int. Cl. G01R 27/02

(52) U.S. Cl. CPC G01R 27/02
USPC 702/65

(57) ABSTRACT

In one preferred form of the present invention, there is provided method 10 of generating at least one image. The method 10 includes applying electrical signals to an individual at various spaced apart nodes; measuring impedance related data between a number of the nodes; and using the impedance related data to generate three dimensional image data.

### FIELD OF THE INVENTION

In preferred forms the present invention relates to imaging systems and methods. In one preferred embodiment there is provided a three dimensional brain imaging method.

### BACKGROUND TO THE INVENTION

X-Ray Computer Tomography or Computer Tomography Scanning (CT Scanning) involves the computation of images from X-rays. CT Scanning has become an important tool for a variety of scans in the medical industry. CT Scanning is commonly used for scanning the head, heart, lungs, abdomen and other body parts of people.

CT Scanning is able to provide high resolution images of high contrast. Tissues having relatively small differences in density can be readily distinguished using CT scanning.

CT scanning does however require the administration of relatively high doses of ionizing radiation. Such ionizing radiation has been shown to have the capability to change the structure of cells and result in cancer and other health conditions. Ionizing radiation has, for example, been shown in studies to have the ability to cause mental retardation and other cognitive problems in some circumstances. For this reason the ionization dosage in CT scans including brain perfusion CT scans is recommend by some organizations to use less than a predetermined number of milligray (absorbed dose).

Adverse effects from the ionizing radiation of CT scanning can be reduced through restricting its use to only essential applications and by the application of certain techniques. Nonetheless, a relatively low but definite risk still exists when a conventional CT scan is taken, despite efforts made to reduce it.

Magnetic Resonance Imaging (MRI) or Magnetic Resonance Tomography (MRT) involves the use of high powered magnetic fields to align atomic nuclei in a subject and radio frequency waves to alter the effect of the magnetization. Depending on the magnetic field gradient the nuclei respond with different rotational magnetic fields which are used to construct an image of the subject.

MRI is known to be useful for producing medial images with high contrast for different soft tissues. This makes the use of MRI a useful technique for imaging the heart, brain, muscles and other soft tissue body parts.

Notably MRI does not use any form of ionizing radiation such as x-rays. Nonetheless, even though no ionizing radiation is involved, there are still considered to be certain health risks. Furthermore, MRI cannot be used in all cases, such as with people who have a pacemaker or a metallic implant.

Applied Potential Tomography (APT) or Electrical Impedance Tomography (EIT) involves the application of electrical fields to a subject. This typically involves placing a number of electrodes at spaced intervals around the subject. Voltages are then applied and the conductivity and permittivity of the subject is inferred from the voltages at the other electrodes.

EIT is a relatively new area of medical imaging research. It is only recently that EIT devices are beginning to be made commercially available for lung imaging. EIT is considered to suffer from a number of issues. One of these issues relates to the inverse nature of the calculation of the image from the voltage data. Skin boundary, location and other issues also affect the resultant image. The resolution provided and methods of image construction are presently not to a standard whereby EIT can provide a competitive alternative to conventional CT Scanning and MRT approaches.

One relatively unknown device in medical imaging comprises ‘fEITER’ detailed in ‘fEITER—a new EIT instrument for functional brain imaging’, J L Davidson et al 2010 J. Phys.: Conf. Ser. 224 012025. The ‘fEITER’ system is not directed to imaging but rather monitoring electrical activity within the brain.

Whilst a background to the invention has been provided by the applicant, it is to be recognised that any discussion in the present specification is intended to explain the context of the invention. It is not to be taken as an admission that the material formed part of the prior art base or relevant general knowledge in any particular country or region.

### SUMMARY OF THE INVENTION

The applicant notes that the present invention is of a broad nature and that system and methods are being developed that can be demonstrated commercially. The general nature of the invention is considered to be disclosed in various embodiments and is considered to provide a substantial contribution to the art.

According to a first aspect of preferred embodiments herein described there is provided a method of generating at least one image comprising: applying electrical signals to an individual at various spaced apart nodes; measuring impedance related data between a number of the nodes; and using the impedance related data to generate three dimensional image data.

Preferably the method includes applying electrical signals to the individual around the individual's head at the various spaced apart nodes; measuring the impedance related data between a number of the nodes; and using the impedance related data to generate 3 dimensional data of the headspace of the individual's head.

Preferably measuring the impedance related data between a number of the nodes comprises measuring the impedances based on a spherical model.

Preferably measuring the impedance related data between a number of the nodes, comprises measuring the impedances of groups of three active nodes, each group forming a delta configuration.

Preferably measuring the impedance related data between a number of the nodes is performed to build a delta star configuration of impedances.

According to a second aspect of preferred embodiments herein described there is provided a system for generating at least one image comprising: an arrangement for applying electrical signals to an individual at various spaced apart nodes; and a data acquisition facility for measuring impedance related data between a number of the nodes.

Preferably the system provides an EEG unit having more at least 10,000 electrodes.

Preferably each electrode is associated with a surface area of less than 1 mm².

According to a third aspect of preferred embodiments herein described there is provided a method of generating at least one image comprising: applying electrical signals to an individual at various spaced apart nodes; measuring impedance related data between a number of the nodes; the measuring of electrical signals including at least one delta configuration impedance measurement; and using a super computing device to generate a three dimensional image data with the at least one delta or star impedance measurement serving to reduce aberrations in the three dimensional image data.

Preferably the at least one delta configuration impedance measurement comprises at least 10⁶ measurements.

Preferably each of the at least one delta configuration measurements comprises the measurement of impedance related data between three active nodes.

Preferably the application of electrical signals includes at least one delta-star configuration impedance measurement, each of the at least one delta-star configuration impedance measurement comprising the measurement of impedance related data between more than three active nodes.

According to a fourth aspect of preferred embodiments herein described there is provided a system for generating at least one image comprising: an signalling arrangement for applying electrical signals to an individual at various spaced apart nodes; a measurement arrangement for measuring impedance related data between a number of the nodes; the measurement arrangement being configured for taking at least one delta or star configuration impedance measurement; and a super computing device for generating three dimensional image data with the at least one delta configuration impedance measurement serving to reduce aberrations in the three dimensional image data. It is to be recognised that other aspects, preferred forms and advantages of the present invention will be apparent from the present specification including the detailed description, drawings and claims.

Further advantages and preferred features will be apparent from the drawings and a reading of the specification as a whole.

The present invention is to be construed beneficially to the applicant.

### BRIEF DESCRIPTION OF DRAWINGS

In order to facilitate a better understanding of the present invention, several preferred embodiments will now be described with reference to the accompanying drawings, in which:

FIGS. 1 and 2 provide a schematic view of a method according to a first preferred embodiment of the present invention;

FIG. 3 provides a schematic view of a method according to a second preferred embodiment of the present invention;

FIG. 4 shows a number of pairs of potential poles;

FIG. 5 illustrates an impedance measurement configuration used in the method shown in FIGS. 3 and 4;

FIGS. 6a to 7b shown a number of different configurations;

FIG. 8 shows an impedance arrangement;

FIG. 9 shows a number of pairs of potential poles;

FIGS. 10 to 15 illustrate a calculation method used in the embodiment of the invention described in relation to FIGS. 3 and 4;

FIG. 16 shows a computer implemented system according to another embodiment; and

FIGS. 17a and 17b illustrate a further preferred embodiment of the present invention.

### DETAILED DESCRIPTION OF THE EMBODIMENTS

It is to be appreciated that each of the embodiments is specifically described and that the present invention is not to be construed as being limited to any specific feature or element of any one of the embodiments. Neither is the present invention to be construed as being limited to any feature of a number of the embodiments or variations described in relation to the embodiments.

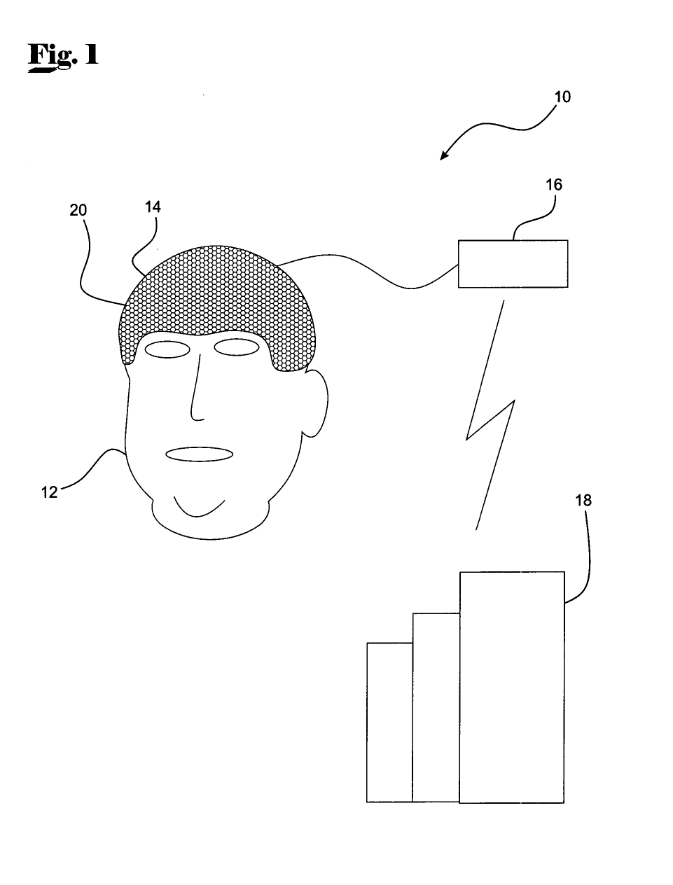

Referring to FIG. 1 there is shown a brain imaging method 10 according to a preferred embodiment of the present invention. The brain imaging method 10 advantageously utilises electroencephalography (EEG) and supercomputing to provide a 3-dimensional high resolution image of subject's brain.

As shown in FIG. 1, an individual 12 is connected to an EEG headpiece 14 that is connected to a unit 16. The unit 16 is in turn connected to a supercomputing device 18 that is adapted to generate a three dimensional image of the head 20 of the individual 12. Advantageously weak alternating current is applied to the head 20 of the individual 12 rather than ionizing radiation or strong magnetic fields.

This is considered to provide significant safety advantages over conventional CT Scanning and MRT. The method 10 employs an advantageous electrical impedance approach which measures impedances in delta-star arrangements. In one advantageous mode of operation the method 10 employs alternating current (AC) at different frequencies and generates a 3-dimensional mapping of tissues.

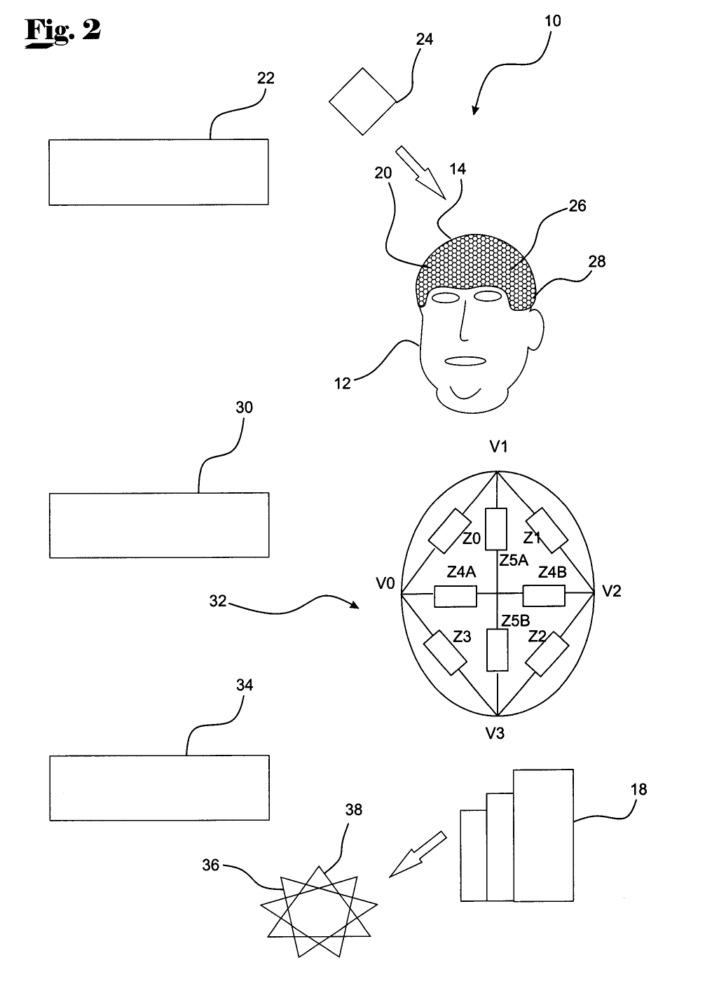

Referring to FIG. 2, the method 10, at block 22, includes applying electrical signals 24 to the head 20 of the individual 12 at various spaced apart nodes 24. The nodes 26 comprise electrical contacts 28 . Unlike conventional EIT scanning the electrical contacts 28 comprise many 10's or 100's of 1000's of electrical contacts over the scalp of the individual 12. In the present embodiment the electrical contacts 28 have a surface area density of at least 200 per square centimetre. Each contact 28 is preferably associated with a surface area less than one square millimetre.

At block 30, the method 10, includes applying electrical signals in delta and star measurement configurations 32 and taking corresponding measurements. The nature of the delta and star measurement configurations 32 is described in further detail below. At block 34, the method 10 includes using the super computing device 18 to generate three dimensional image data 36 with the measurements from the delta and star measurement configurations 32 serving to complement each other to reduce aberrations in the three dimensional image data 36.

In the embodiment the electrical contacts 28 comprises electroencephalography (EEG) electrodes. The super computing device 18 advantageously provides a reconstructed 3-dimensional high resolution image 38 of the individuals' brain. In the embodiment the super computing device 18 comprises a supercomputing grid (grid computing).

Although yet to be demonstrated, it is considered that the quality of the images should rival that of magnetic resonance imaging (MRI) and CT Scanning. In addition, the applicant considers it conceivable that the proposed technology could eventually lead to safer and cheaper whole body imaging.

The head piece 14 is considered to form another embodiment of the present invention. As discussed the headpiece 14 comprises an EEG system with hundreds of thousands of electrodes. Presently EEG headpieces for measuring brain response comprise no more than 256 electrodes, which is considered to be the state-of-the-art.¹

Although a very large number of measurements from electrode pair combinations must be used to reconstruct the 3-dimensional image 38 it is possible to do this with the supercomputing device 18. The cost benefit analysis of the method 10 is considered advantageous because a super computer does not have to be provided at the location at which the measurements are taken.

Cheaper mass production should allow relatively widespread use of the present brain imaging method. MRI and CT scanning, in comparison, use bulky and expensive equipment. The proposed technique may assist in earlier diagnosis of brain cancer in multiple locations within poorer countries, as well as more affluent regions. Profit can be made by the organization that provides the supercomputing facility.

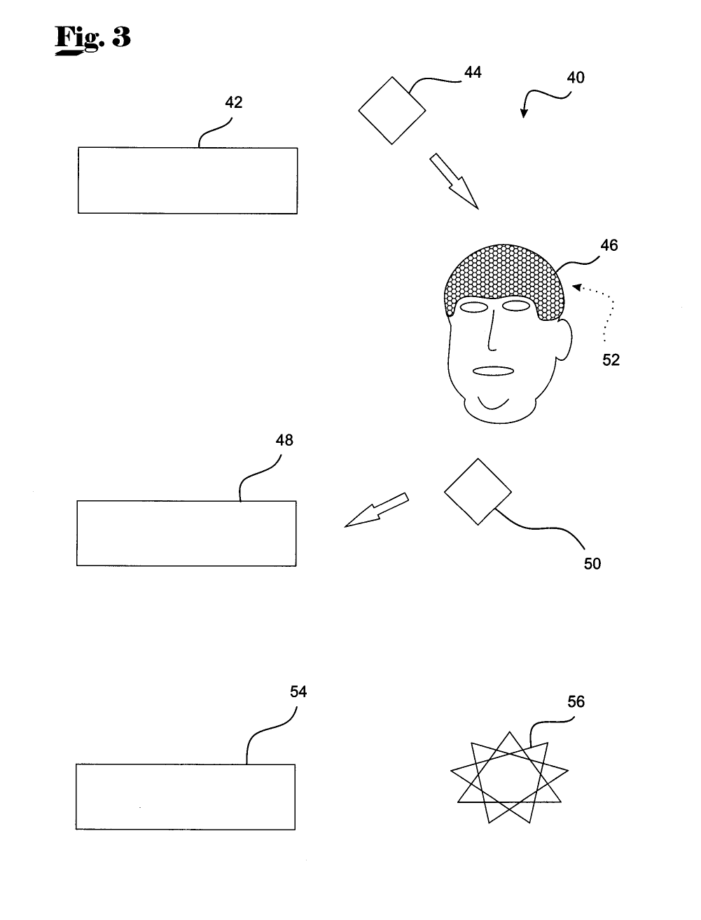

Another preferred embodiment of the present invention in shown in FIG. 3. In the embodiment, a method 40, at block 42, includes applying electrical signals 44 around an individual's head 46. At block 48 the method 40 includes measuring impedance related data 50 between a number of spaced apart nodes 52. At block 54 the method 40 includes using the impedance related data 50 to generate a 3-dimensional headspace 56 of the individual's head 46. Weak alternative current is applied at levels below perception and is considered not to present a risk.⁵

Although different to the present method, conventional Electrical Impedance Tomography (EIT) when studied in relation to the chests of 12 normal individuals, 1 mA current was considered to be used safely over frequencies ranging from 9.6 to 614.4 kHz.⁶

In a more recent study, seven patients with brain abnormalities including stroke and brain tumours were safely subjected to approximately 3 μA current at frequencies of 2 kHz to 1.6 MHz via EEG electrodes.⁷ The applicant does however realise that further testing may be required with this particular high resolution imaging of the brain. The applicant considers that conventional EEG/EIT technology cannot be used for this purpose.

Before considering the star and delta measurement configurations 32, it is necessary to define the following impedance related variables.

V(p)=Electric potential between two electrodes in millivolts (mV).

Z=Impedance (resistance in tissues) in kilo-ohms (kΩ)^{5,7}

Z_{R}=Resistance (R) (ohmic)

Z_{C}=Capacitance

Z_{T}=Total impedance

ω=Angular frequency of the AC current

j=Imaginary number

Total impedance (Z_{T})=Z_{R}Z_{C}

Z_{T}=R+(1/jωC)

In the method 40 an array of a large number of electrodes, distributed with approximately equal spacing, is placed around the individual's head 46. As discussed the number of electrodes is many fold greater than the number conventionally used for electroencephalography (EEG) measurements.

For the purposes of this explanation, a spherical head model is assumed. Nonetheless in other embodiments the method includes utilizing location facilities for defining the exact location of each or groups of electrodes used.

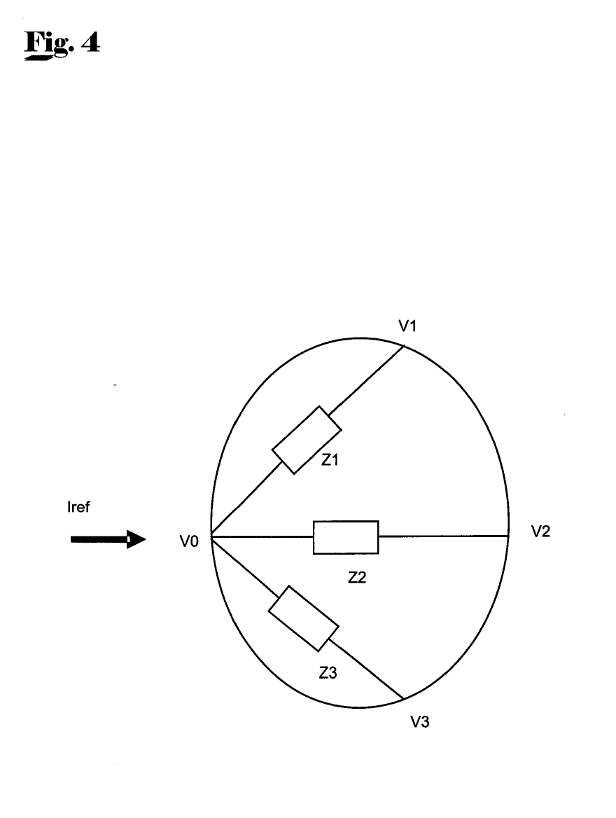

Referring to FIG. 4, given the small distance between each electrode, a linear path taken by reference current (I_{ref}) is assumed in the spherical model of the method 40 in FIG. 3. I_{ref} is tested at different frequencies to determine tissue composition as will be described. In FIG. 4 three example impedances (Z₁ to Z₃), with linear current paths are shown. The reference node (V₀) is shown on the left.

Polar coordinates are not used in the proposed method of calculation of impedances of the tissue within the individual's spherical head space. Also, there is no reference point because the entire 3-dimensional head space is to be mapped in terms of impedances rather than relative voltages.

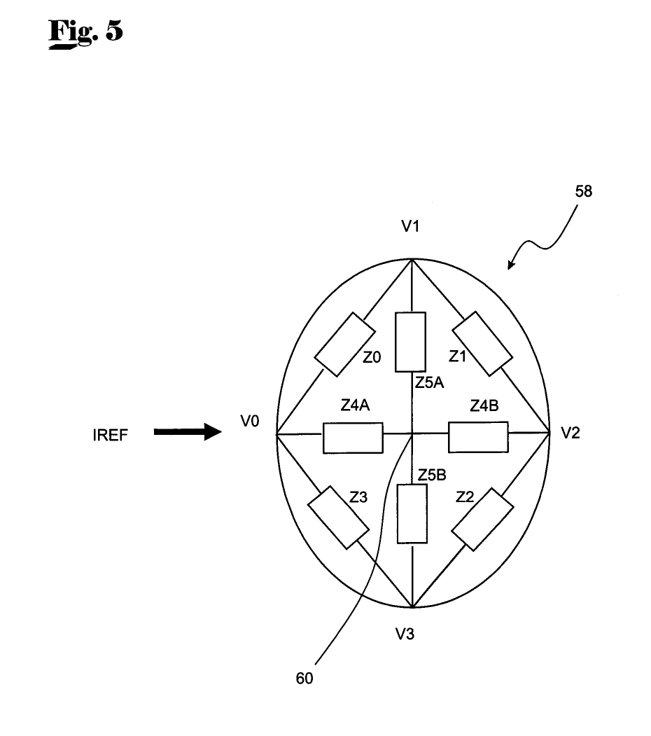

FIG. 5 illustrates a delta-star impedance measurement configuration 58 used in the method 40. The delta-star impedance measurement configuration 58 contains a node 60 in the headspace and is to be used first. A reference current IREF is applied at electrode V0 and impendences Z1 to Z5B are estimated based on the resultant voltages V0 to V3. In the star arrangement electrodes at V0 to V3 are active.

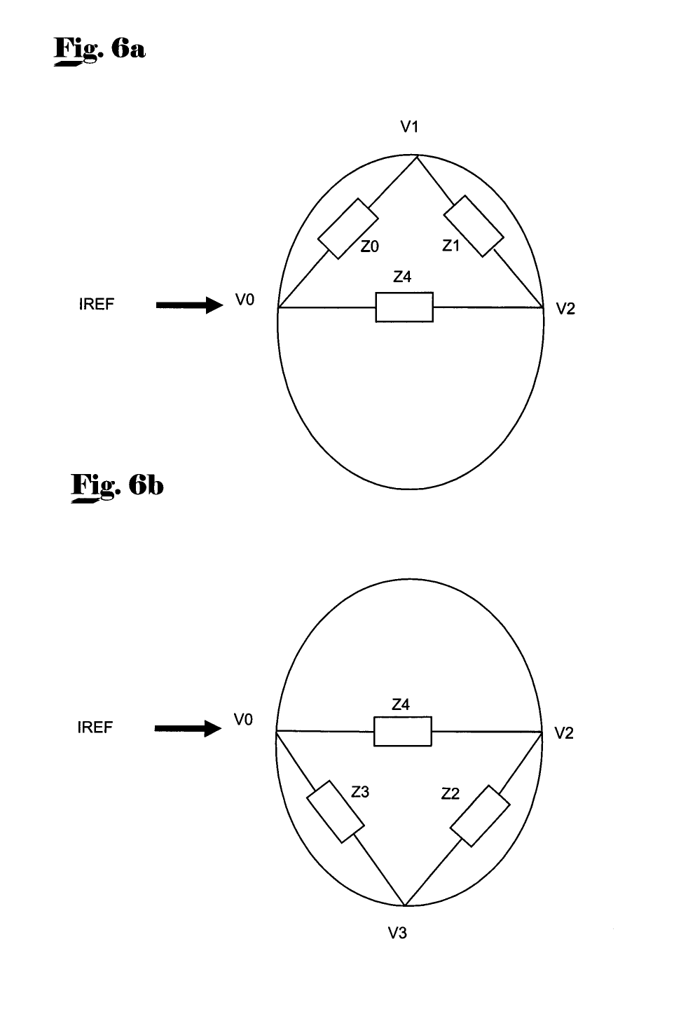

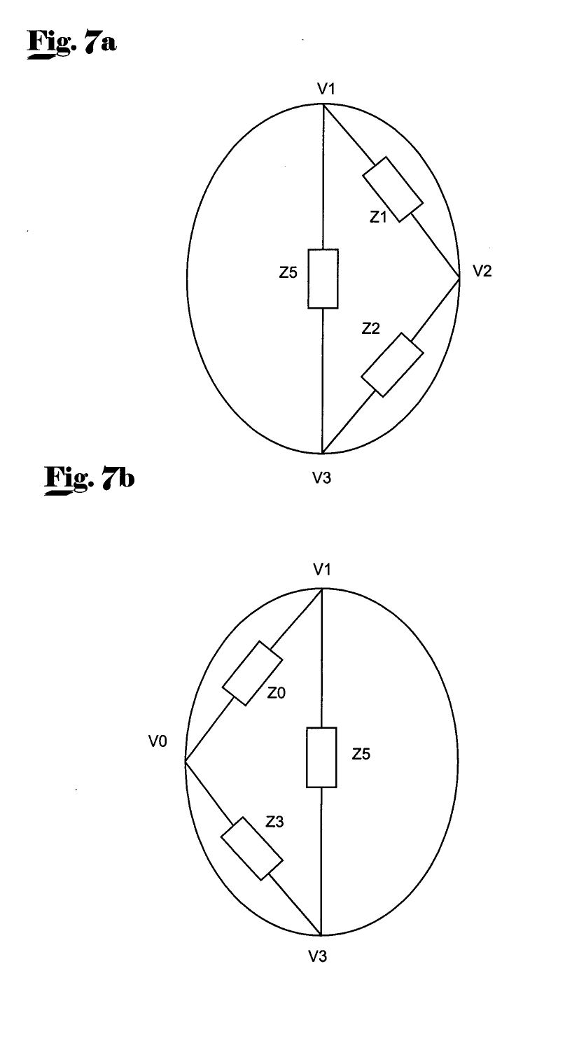

Once measurements from real tissue have been obtained with the delta-star arrangement, delta arrangements are used, to confirm accuracy of the delta-star arrangement estimated. This is illustrated in FIGS. 6a and 6b where two separate delta measurements can be used to remove the current path V1 to V3. Further delta configuration measurements are taken as shown in FIGS. 7a and 7b to remove the current path V0 to V2.

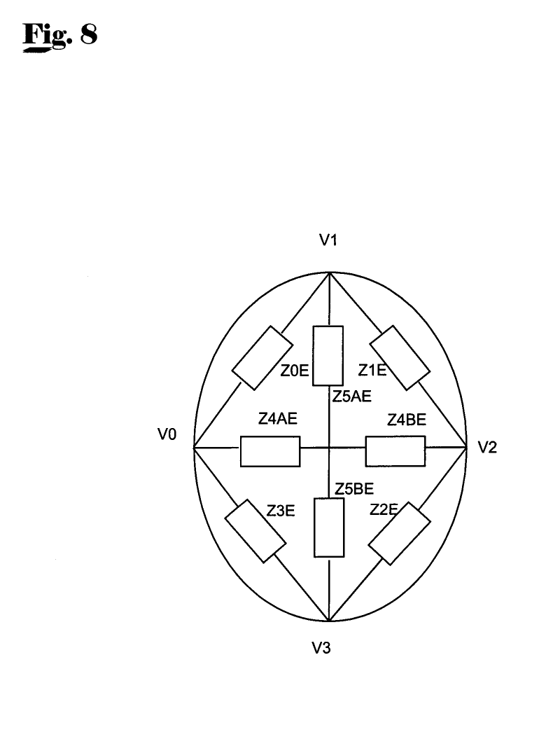

As shown in FIGS. 6a to 7b each delta measurement configuration comprises the measurement of impedance related data between three active nodes. The measurement between three active nodes to remove other direct current paths and obtain impedance related data is considered to be advantageous. When combined with the deltastar measurement configuration data useful information in the estimation of the impedance arrangement shown in FIG. 8 is obtained.

It is considered advantageous to have both the delta and delta-star arrangements to allow interpolation for missing values due to poor electrode contacts and unusual values or noise, which can result from sweat on electrodes and affect capacitance at the skin/electrode boundary.

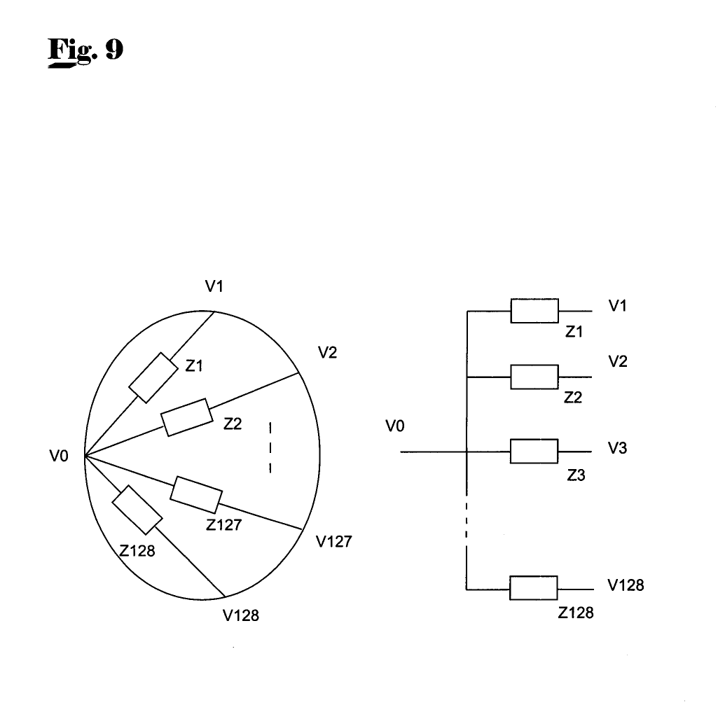

Although the EEG electrode set for the proposed technique is to include many more electrodes than are conventionally used, such as tens or hundreds of thousands of electrodes, one can consider an example of 128 pairs of potential poles, each with 128 complex impedances to be computed. Such an arrangement is shown in FIG. 9.

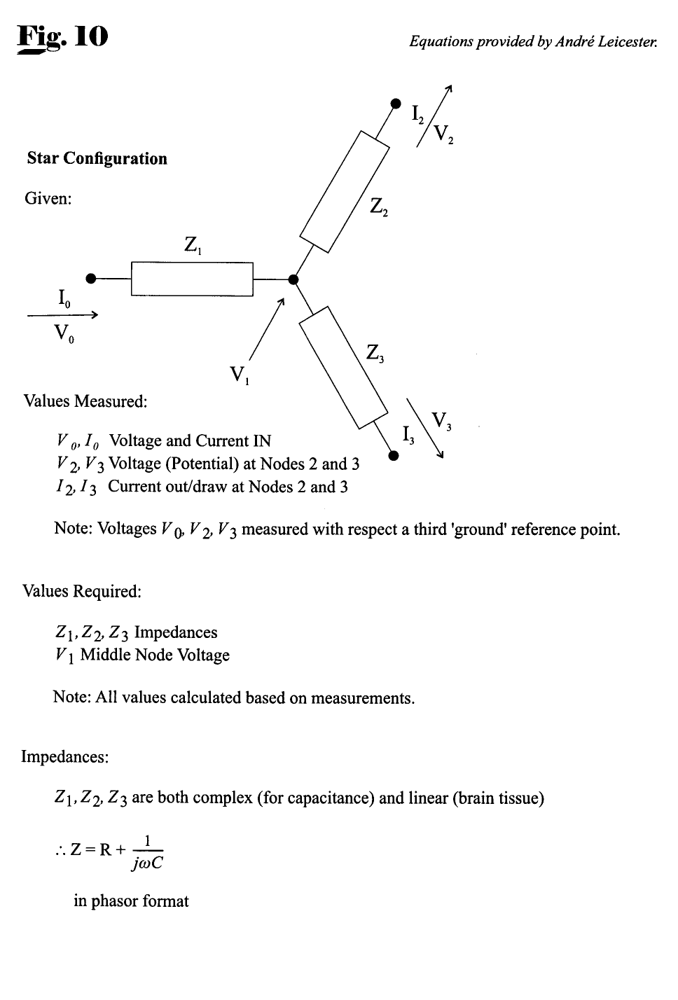

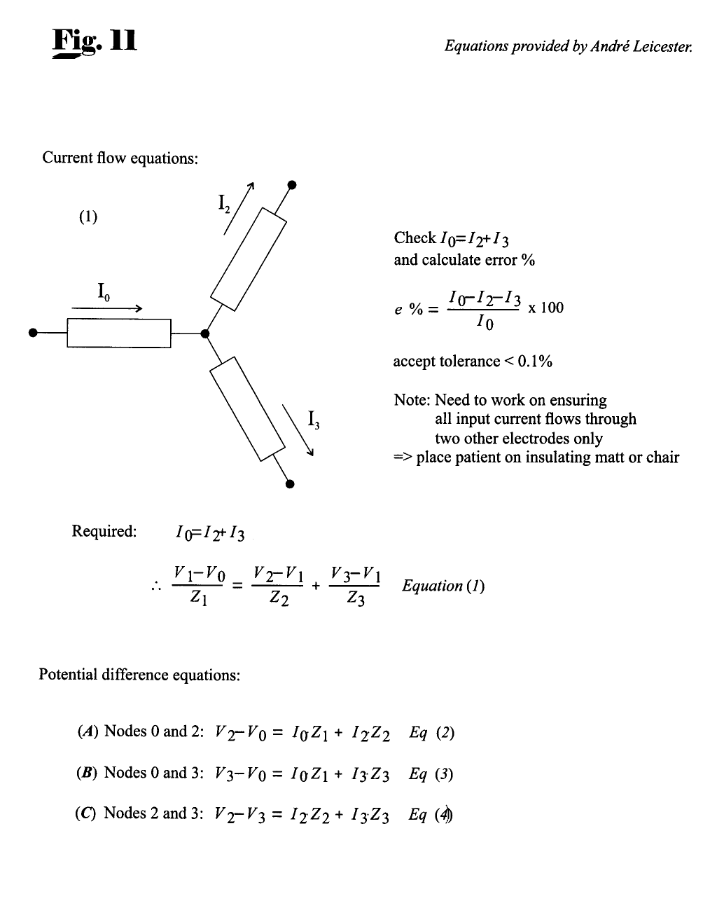

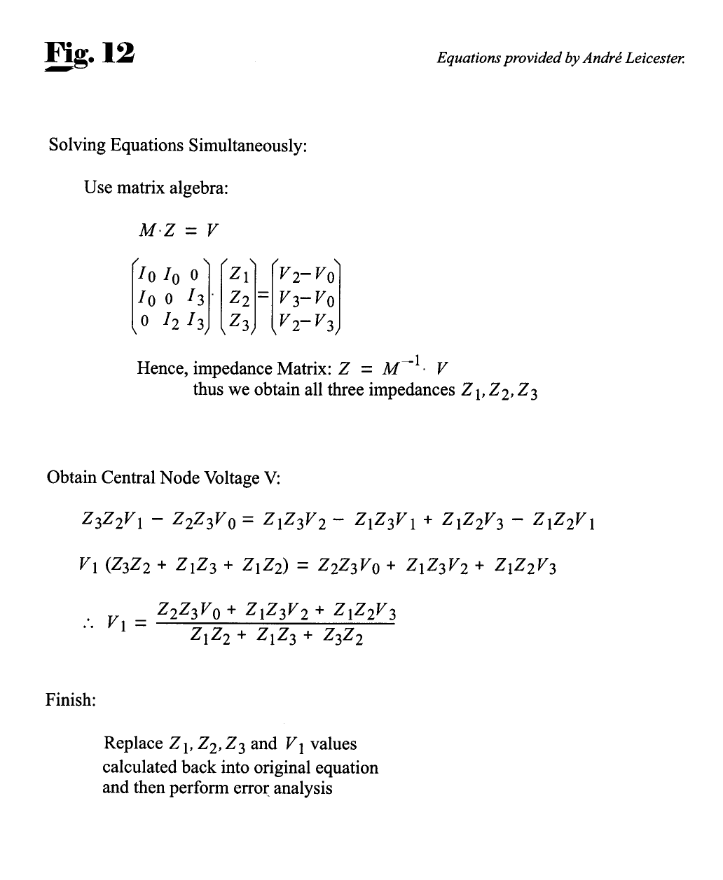

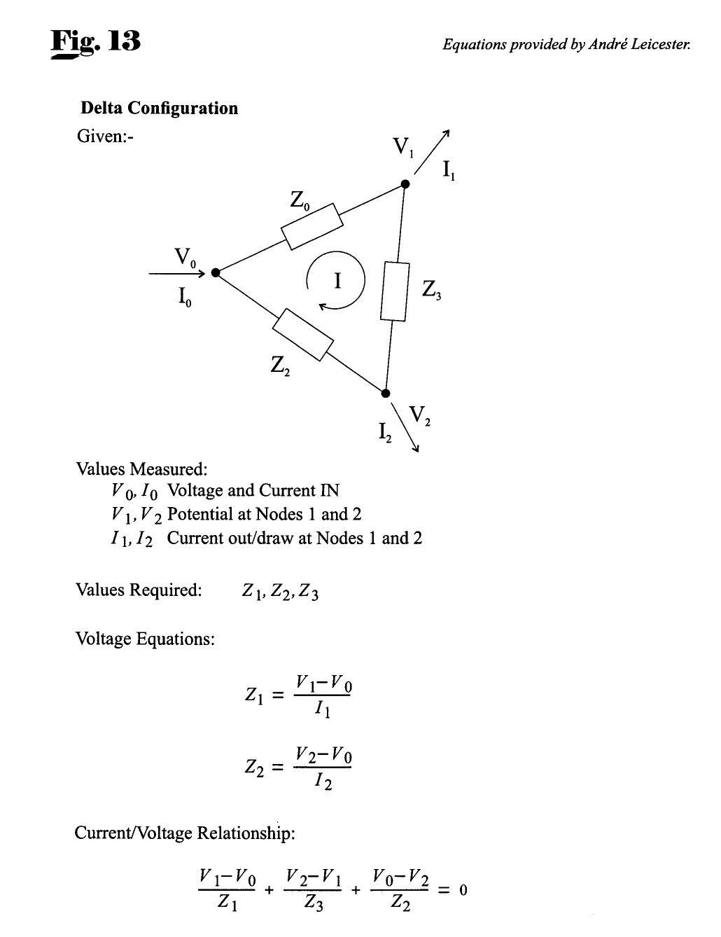

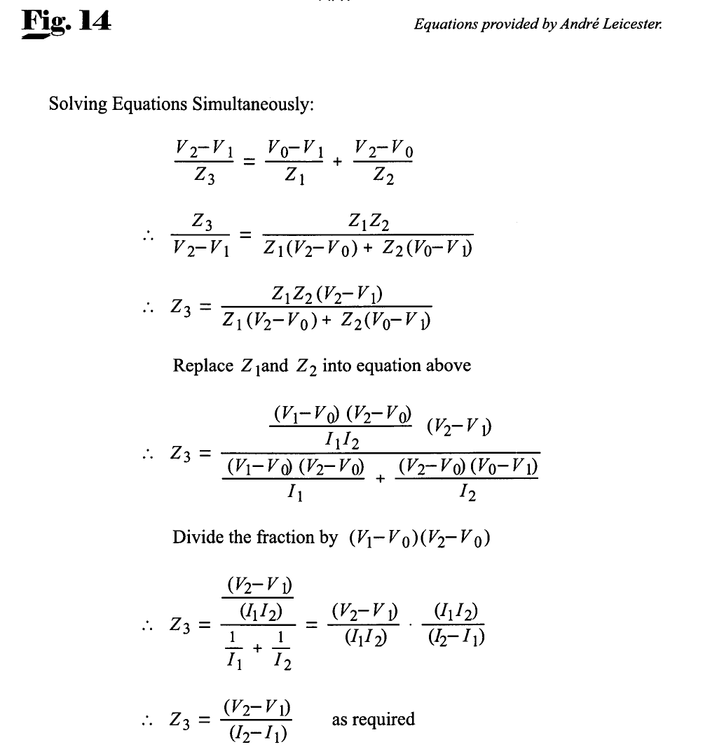

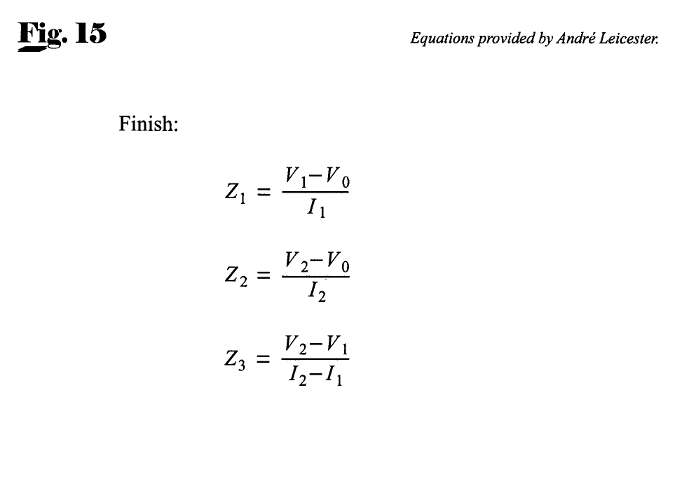

As indicated above, the actual distance between poles needs to be known to determine the impedance per linear unit of measurement. This would be known from the electrode set design and model used. In the case of 128 electrode pairs, the total number of combinations of electrodes in pairs and hence measurements is 128 choose 2=128*127/2=8128 measurements. Notably delta measurements are made by computer after direct measurements have been taken using predetermined techniques. A delta star calculation method is shown in FIGS. 10 to 15.

Advantageously in the present embodiment measurements are taken simultaneously at different frequencies. In the method, in order to determine tissue composition, tables of tissue impedance data are used. Known data of tissues have been published (reviewed by Gabriel et al.),⁸ as impedance changes with frequency. At 128 choose 2, if 10 frequency levels were used, this would be about 8.13×10⁴ measurements. Using 1024 electrode pairs, there would be about 5.2×10⁵ measurements at a single frequency or about 5.2×10⁶ measurements using 10 frequency levels. With hundreds of thousands of electrodes, the number of measurements increases exponentially by several orders of magnitude.

With respect to the tissue tables, tissue mapping data could be checked against an MRI image template of the same brain to adjust and calibrate the tables and confirm data tissue values. The tables are used by the supercomputing device 18 to reconstruct the density and other characteristics of the headspace.

With respect to resolution or sharpness of the resultant image, the 3-dimensional head space would be divided into blocks, units or “voxels” defined by impedances. The standard resolution for MRI and CAT scanning is 1 cubic mm voxels. Assuming that the upper end of human brain volume is 1300 cc, this is 1300×(10×10×10) cubic mm=1 300 000 cubic mm. If one can assume that the brain is a sphere of radius “r” and Volume=4/3π×r³, then r=67.71 mm. Surface area=4π×r²=57 595 mm². Thus if there were say 100 000 electrodes, each would need to define 0.6 square mm of the brain at its surface. The applicant considers that this is practical.

Regarding the nature for the measurements, there may be a small delay required between measurements, due to time for current flow across a region of tissue to stabilize. The applicant considers that the minimum time to take readings could be readily determined by standard measurements. The applicant considers that this may mean that the time to gather data may be more than the time needed to perform computations and to reconstruct a 3-dimensional image using a supercomputer. For 128 electrode pairs choose 2, with a measurement time of 10 milliseconds per electrode pair, the time needed would be about 1 minute and 20 seconds. With a measurement time of 100 milliseconds per electrode pair, the required time would be 13.5 minutes.

By taking measurements simultaneously at different frequencies, delays advantageously do not necessarily require the person undergoing brain imaging to wait. As noted, measurements are preferably done simultaneously at different frequencies. There can also be multiple reading units. The measurements could be stored in a data array and then extracted as the calculations are performed, although it would require software to do this. The final result would be a 3-dimensional image.

Thus having described the method it would be apparent that the method 40 comprises: applying electrical signals to an individual at various spaced apart nodes; measuring impedance related data between a number of active nodes; and using the impedance related data to generate three dimensional image data.

EIT measurements are considered by the applicant to be the most closely related technique to the proposed method. EIT uses arrays of electrodes, such as 30 electrodes in each array, placed on either side of tissue. It has various applications, such as detection of breast tumours by mammography.⁹ Previous attempts to use EIT for human brain imaging appear to have largely been unsuccessful.¹⁰ Although image quality with EIT is poor, efforts are being made to improve this.¹¹

To the best of the applicant's present knowledge, nobody has used or has proposed to use the electrical impedance model based on resistances in delta-star arrangements described herein for the purposes of brain imaging. Other methods have been used instead such as a cuboid model employing two flat arrays of 30 electrodes, using a gradient field approach.⁹ The applicant considers that this is not suitable for a spherical model of preferred embodiments.

Although a spherical model has been used with EIT for the purposes of developing techniques to image stroke damage in the brain, for example recently by Ahn et al.,¹² measuring impedance related data for the purpose of reconstruction appears never to have been used.

The approach of the present invention requires the use of tissue related data and uses a supercomputer for computations involved with the high number of electrodes. The applicant's have appreciated that a spherical head model for brain imaging enables simpler optimisation than if applied to other regions of the body. This is considered to simplify calculation in a super computer environment. By interpolation the method is considered to be able to establish a tissue density field and thus construct a 3-dimensional field for imaging. As would be apparent a non-spherical model may also be used.

In order to develop the accuracy of the present method for very high resolution applications, it is considered likely to be necessary to develop techniques to control noise, known to be a significant problem in EIT.

In terms of capacitance noise, the noise can be highly variable at the skin/electrode boundary due to oil or sweat on skin creating problems to perform imaging. Notably, in EIT and the established imaging techniques of CAT and MRI, Jacobian matrices¹³ are used to compensate for noise due to poor electrode contact.⁹

As such mathematics to address skin capacitance at the skin/electrode boundary will be required to provide the necessary resolution and account for noise. Although databases of different conductivities of head tissues exist (reviewed by Gabriel et al.),⁸ abnormal tissues (e.g. brain tumours) have compositions and thus conductivities which are different from normal tissue, leading to difficulties in accurate tissue type prediction. Mathematics to calculate capacitance are “Jacobian matrices” and appropriate values and can be readily obtained by measurement.

The applicant's have, according to another embodiment, provided an advantageous treatment of capacitance at the skin/electrode boundary. As part of the noise correction, in the embodiment, it is preferable that exclusion of areas of high noise (“capacitance”) is done by signal subtraction. The supercomputer determines which electrodes to exclude for imaging data due to capacitance issues, or alternatively, an average signal from neighbouring electrodes.

Moreover, the supercomputer preferably excludes electrodes producing noise in real-time. With 100 000s electrodes, there are sufficient electrodes to give many alternative routes for 3-dimensional imaging. As such a supercomputer can continuously monitor capacitance to use only the electrodes without “noise” to produce an image.

In the proposed method, electrodes applied to the scalp move with the individual, eliminating noise due to movement and reducing the cost of the equipment. In the case of CT and MRI imaging movement is a major source of noise.¹⁴ Hence the need for subjects undergoing CT Scanning or MRT to be immobilised and the use of bulky equipment. The present embodiments do not suffer from this disadvantage as the electrodes are fixed to the subject's head.

As part of the present disclosure it is to be appreciated that impedance type data is to be understood as impedance (Ohms) or voltage (Volts), current (Amps) with phase shift. Impedance involves a base magnitude phase shift of the sine wave pattern of voltage or current, and follows Ohms law in alternating current space. This sine wave is typical of AC current (i.e. “power wave”) seen on an oscilloscope screen. Using AC current at higher frequencies, Z_{C} would almost disappear, enabling R=V/I to be used to approximate voltage (V) and current (I) because: Z_{C}=1/jωC, where is “angular” frequency of AC current, C is capacitance and j is an imaginary number. Angular frequency is 2π×frequency of AC current in “Hz” (Hertz which is cycles per second). The use of direct impedance type data, that is impedance, is preferred due the reconstruction process and use of tables; rather than havening to determine impedance from voltage, current and phase shift.

In order to reconstruct a 3-dimensional image of the brain, it is necessary to determine both tissue density and a 3-dimensional location. As discussed use of alternating current at different frequencies enables the determination of tissue densities from impedance values, based on data in existing databases (see review by Gabriel et al.).⁸ In the present embodiments it proposed that it is possible to map the entire 3-dimensional head space using a delta-star arrangement of impedances.

As part of the approach the applicants consider that it should eventually be possible to use a single optical fibre as part of the electrode lead, as individual electrodes can be digitally coded. Furthermore, it is expected that in time it should be possible to develop a wireless electrode set for brain imaging. Initial experiments for mathematical optimisation could use a standard EEG electrode set and lead. It is further envisaged that the embodiments for brain imaging described could form the basis of whole body imaging using the same technology.

### REFERENCES

1. Usakli, A. B. (2010). Improvement of EEG signal acquisition: An electrical aspect for state of the art of front end. Computational Intelligence and Neuroscience. Available from: Hindawi Publishing Corporation. [8 Feb. 2012].
2. Yu, L., Liu, X., Leng, S., Kofler, J.M., Ramirez-Giraldo, J. C., Qu, M., Christner, J., et al. (2009). Radiation dose reduction in computed tomography: Techniques and future perspective. Imaging in Medicine, 1(1), 65-84.
3. Raelson, C. A., Kanal, K. M., Vavilala, M. S., Rivara, F. P., Kim, L. J., Stewart, B. K., et al. (2009). Radiation dose and excess risk of cancer in children undergoing neuroangiography. American Journal of Roentgenology, 193, 1621-1628.
4. Huang, A. R. and Segal, B. A literature review of the safety of medical body area network devices in magnetic resonance imaging. 2011 5^{th} International Symposium on Medical Information and Communication Technology (ISMICT), pp. 127-129. Available from IEEE Digital Library. [8 Feb. 2012].
5. Chatterjee, I., Wu, D. and Gandhi, O. P. (1986). Human body impedance and threshold currents for perception and pain for contact hazard analysis in the VLR-MF band. IEEE Transactions on Biomedical Engineering, 33(5), 486-494.
6. Brown, B. H., Barber, D. C., Morice, A. H. and Leathard, A. D. (1994). Cardiac and respiratory related electrical impedance changes in the human thorax. IEEE Transactions on Biomedical Engineering, 41(8), 729-734.
7. Romsauerova, A., McEwan, A., Horesh, L., Yerworth, R., Bayford, R. H. and Holder, D. S. (2006). Multi-frequency electrical impedance tomography (EIT) of the adult human head: Initial findings in brain tumours, arteriovenous malformations and chronic stroke, development of an analysis method and calibration. Physiological Measurement, 27, S147-S161.
8. Gabriel, C., Peyman, A. and Grant, E. H. (2009). Electrical conductivity of tissue at frequencies below 1 MHz. Physics in Medicine and Biology, 54, 4863-4878.
9. Boverman, G., Isaacson, D., Saulnier, G. J. and Newell, J. C. (2009). Methods for compensating for variable electrode contact in EIT. IEEE Transactions on Biomedical Engineering, 56(12), 2762-2772.
10. Holder, D. S. Electrical Impedance Tomography of brain function. World Automation Congress 2008, pp. 1-6. Available from IEEE Digital Library. [8 Feb. 2012].
11. Bera, T. K., Biswas, S. K., Rajan, K. and Nagaraju, J. (2011). Improving image quality in electrical impedance tomography (EIT) using projection error propagation-based regularization (PEPR) technique: A simulation study. Journal of Electrical Bioimpedance, 2, 2-12.
12. Ahn, S., Jun, S. C. and Woo, E. J. Numerical simulation of frequency-difference EIT using multi-shell concentric spherical head model. 2011 8^{th} International Symposium on Noninvasive Functional Source Imaging of the Brain and Heart; and 2011 8^{th} International Conference on Bioelectromagnetism (NFSI and ICBEM), pp. 1-4. Available from IEEE Digital Library. [8 Feb. 2012].
13. Leow, A. D., Yanovsky, I., Chiang, M.-C., Lee, A. D., Klunder, A. D., Lu, A., et al. (2007). Statistical properties of Jacobian maps and the realization of unbiased large-deformation nonlinear image registration. IEEE Transactions on Medical Imaging, 26(6), 822-832.

14. Thielemans, K., Asma, E. and Manjeshwar, R. M. (2009). Mass-preserving image registration using free-form deformation fields. Nuclear Science Symposium Conference Record, pp. 2490-2495. Available from IEEE Digital Library. [8 Feb. 2012].

15. Brown, B. H. and Barber, D. C. (1995). Low-cost functional imaging—electrical impedance tomography. Proceedings of the First Regional Conference of Engineering in Medicine and Biology Society, 1995; and 14^{th} Conference of the Biomedical Engineering Society of India, pp. 1.7-1.8. Available from IEEE Digital Library. [8 Feb. 2012].

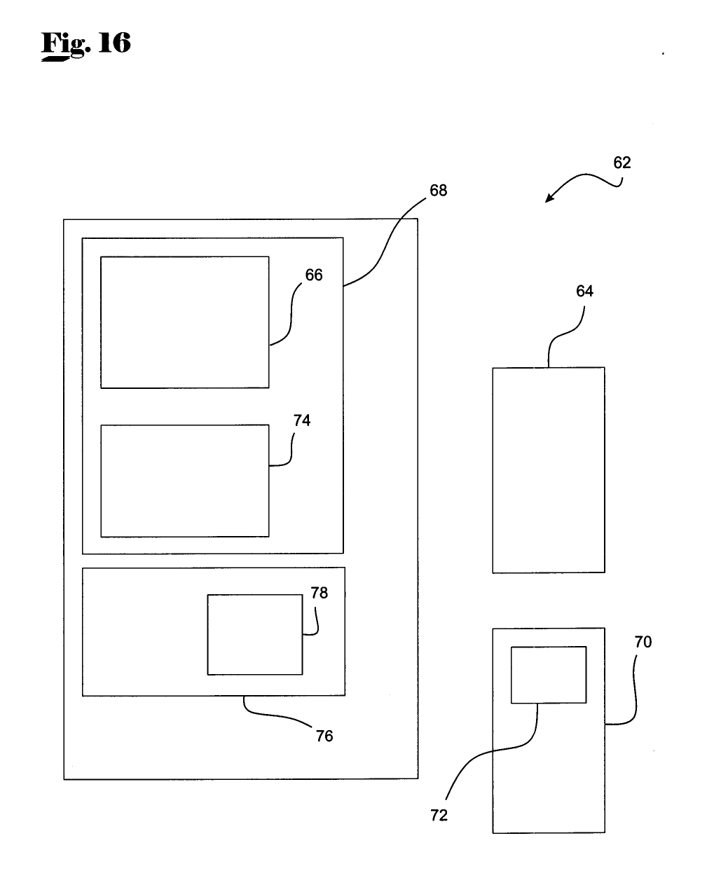

FIGS. 10 to 15 illustrate a calculation method used as referred to above. Algebraic solutions to show how all values of V (voltage), I (current) and Z (impedance) can be obtained for star and then delta configurations. Matrix algebra is used to obtain Z values with simultaneous solutions to equations for potential differences between nodes. Whilst preferred methods have been described preferred embodiments may also comprise systems. For example, as shown in FIG. 16, in one embodiment there is provided a system 62 for generating at least one image 64. The system comprises a signalling arrangement 66 in the form of a headpiece unit 68 for applying electrical signals to an individual 70 at various spaced apart nodes 72. The head piece unit 68 also provides a measurement arrangement 74 for measuring impedance related data between a number of the nodes 72. The measurement arrangement 74 is configured for taking at least one delta configuration impedance measurement. The system further includes a super computing device 76 for generating three dimensional image data 78, with the at least one delta configuration impedance measurement serving to reduce aberrations in the three dimensional image data. Other systems according to the invention would be plainly apparent.

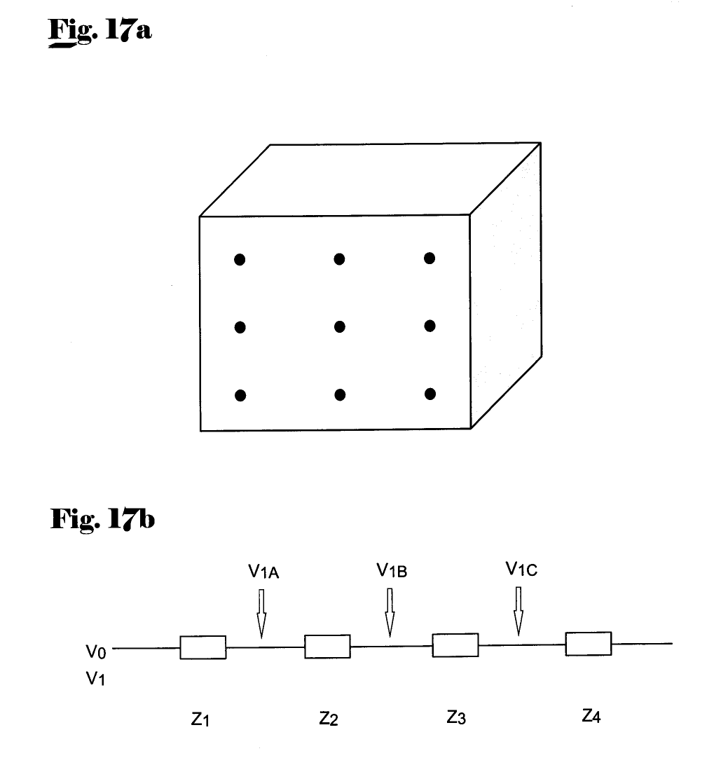

In yet a further method according to a preferred embodiment shown in FIG. 17a, electrode arrays are positioned on the body surface. The example provided comprises a cube with planar faces (modelling the head). The dots indicate regular spacing of electrodes in a plane. The opposing plane in the cube would have an identical array of dots.

Voltages are measured between corresponding dots (electrodes) on the opposing planar faces (not shown above). Due to the large number of electrodes (as in the delta-star method), a linear path is assumed for the reference current between any corresponding pairs of electrodes. The voltage drop is sampled at nodes of the star (not delta) arrangement in the following example shown in FIG. 17b for V1A, V1B and VIC. However, this occurs at multiple points in a linear path, not necessarily just three points.

Voltage drop measured would be proportional to tissue density, in the manner already described in relation to FIGS. 1 to 16. Therefore, there would be no need for complex calculations because linear modelling would be sufficient. No matrix algebra would be required to evaluate impedances. Furthermore, the number of combinations of electrode pairs (and measurements) does not rise exponentially with the number of electrode pairs, as in the delta-star method. Thus instead of using a supercomputer, calculations could be done using a dedicated chip.

Instead of the above example of a cube, any polyhedron with opposing faces could be used. Therefore, a spherical head model would be approximated by a polyhedron of many faces. Each set of electrodes within one given face would be opposed at another face of the polyhedron. From the speed of electricity, a computer could automatically obtain the distances and dimensions required to model the 3-dimensional space. Therefore, this method is on one level more applicable to whole body imaging than use of the delta-star method of calculating impedances because the calculations are relatively simpler.

Notably, as described the method envisages applying electrical signals to an individual at various spaced apart nodes; measuring impedance related data between a number of the nodes; and using the impedance related data to generate three dimensional image data.

A couple of options for the electrode set can be suggested for whole body imaging. Firstly, a suit with imbedded electrodes to cover the body, rather like the EEG headpiece (FIG. 1, object 14) proposed for 3-dimensional brain imaging. Secondly, flat rectangular sets of electrodes (sheets), which wrap around sections of the body. These would be secured in the same manner as a sphygmomanometer (blood pressure monitor) cuff, with Velcro strips. Such an electrode suit or sheets would need to contain segments of electrodes in polyhedral arrangements, which enable any two given polyhedral faces to be in opposition. The second option for whole body imaging of people of different height and body proportions is more practical than the first.

It is to be recognised that various alterations and equivalent forms may be provided without departing from the spirit and scope of the present invention. This includes modifications within the scope of the appended claims along with all modifications, alternative constructions and equivalents. There is no intention to limit the present invention to the specific embodiments shown in the drawings. The present invention is to be construed beneficially to the applicant and the invention given its full scope. For example, the term tag indicator is to be given a broad construction.

In the present specification, the presence of particular features does not preclude the existence of further features. The words ‘comprising’, ‘including’ and ‘having’ are to be construed in an inclusive rather than an exclusive sense.

The claims defining the invention are as follows:

1. A method of generating at least one image comprising: applying electrical signals to an individual at various spaced apart nodes; measuring impedance related data between a number of the nodes; and using the impedance related data to generate three dimensional image data.

2. A method as claimed in claim 1 including applying electrical signals to the individual around the individual's head at the various spaced apart nodes; measuring the impedance related data between a number of the nodes; and using the impedance related data to generate 3 dimensional data of the headspace of the individual's head.

3. A method as claimed in claim 1 wherein measuring the impedance related data between a number of the nodes comprises measuring the impedances based on a spherical model.

4. A method as claimed in claim 1 wherein measuring the impedance related data between a number of the nodes, comprises measuring the impedances of groups of three active nodes, each group forming a delta configuration.

5. A method as claimed in any one of claims 1 wherein measuring the impedance related data between a number of the nodes is performed to build a delta star configuration of impedances.

6. A system for generating at least one image comprising: an arrangement for applying electrical signals to an individual at various spaced apart nodes; and a data acquisition facility for measuring impedance related data between a number of the nodes.

7. A system as claimed in claim 6 wherein the system provides an EEG unit having more at least 10,000 electrodes.

8. A system as claimed in claim 7 wherein each electrode is associated with a surface area of less than 1 mm².

9. A method of generating at least one image comprising: applying electrical signals to an individual at various spaced apart nodes; measuring impedance related data between a number of the nodes; the measuring of electrical signals including at least one delta configuration impedance measurement; and using a super computing device to generate a three dimensional image data with the at least one delta or star impedance measurement serving to reduce aberrations in the three dimensional image data.

10. A method as claimed in claim 9 wherein the at least one delta configuration impedance measurement comprises at least 10⁶ measurements.

11. A method as claimed in claim 9 wherein each of the at least one delta or star configuration measurements comprises the measurement of impedance related data between three active nodes.

12. A method as claimed in claim 9 wherein the application of electrical signals includes at least one delta-star configuration impedance measurement, each of the at least one delta-star configuration impedance measurement comprising the measurement of impedance related data between more than three active nodes.

13. A system for generating at least one image comprising: an signalling arrangement for applying electrical signals to an individual at various spaced apart nodes; a measurement arrangement for measuring impedance related data between a number of the nodes; the measurement arrangement being configured for taking at least one delta or star configuration impedance measurement; and a super computing device for generating three dimensional image data with the at least one delta configuration impedance measurement serving to reduce aberrations in the three dimensional image data.
